(19) United States
(12) Patent Application Publication
(10) Pub. No.: US 2025/0294905 A1
(43) Pub. Date: Sep. 18, 2025

(54) IMAGE SENSORS AND METHOD OF MANUFACTURING THE SAME

(71) Applicant: Taiwan Semiconductor Manufacturing Company, Ltd., Hsinchu (TW)

(72) Inventors: Wen-Chang Kuo, Tainan City (TW); Chieh-En Chen, Tainan City (TW); Jen-Cheng Liu, Hsin-Chu City (TW); Yen-Yu Chen, Kaohsiung City (TW); Yen-Ting Chiang, Tainan City (TW); Wen Hsiang Tu, Kaohsiung City (TW); Shyh-Fann Ting, Tainan City (TW); Chen-Hsien Lin, Tainan City (TW)

(21) Appl. No.: 18/603,629

(22) Filed: Mar. 13, 2024

(51) Int. Cl. H01L 27/146

(52) U.S. Cl. CPC H10F 39/807; H10F 39/011; H10F 39/802; H10F 39/811

(57) ABSTRACT

Various embodiments of the present disclosure are directed towards a semiconductor device including a plurality of photodetectors disposed within a substrate, where the substrate has a front-side opposite a back-side. The semiconductor device includes a floating diffusion node disposed in the substrate, where the photodetectors are disposed around the floating diffusion node. A trench isolation structure is disposed within the substrate and laterally surrounds the photodetectors. The trench isolation structure includes a first isolation structure disposed in the substrate and having a first depth, where the first isolation structure is disposed between adjacent photodetectors and is laterally offset from the floating diffusion node. The trench isolation structure includes a second isolation structure extending from the back-side of the substrate towards the floating diffusion node, where the second isolation structure directly overlies the floating diffusion node and has a second depth less than the first depth.

### BACKGROUND

Image sensors are solid-state devices that are configured to convert incoming light (e.g., photons) into an electrical signal. The electrical signal is then provided to a processor that can convert the electrical signal to data that can be stored and/or viewed by a user. Integrated chips (ICs) with image sensors are used in a wide range of modern day electronic devices, such as cell phones, security cameras, medical devices, etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-3 illustrate various views of some embodiments of an image sensor having a trench isolation structure including a partial depth isolation structure and a full depth isolation structure.

FIG. 4 illustrates a top view of some embodiments of an image sensor having a full depth isolation structure that includes a tab structure surrounding a partial depth isolation structure.

FIG. 5 illustrates a cross-sectional view of some embodiments of the image sensor of FIG. 4.

FIG. 6 illustrates a cross-sectional view of some embodiments of an image sensor with a wedge shaped partial depth isolation structure.

FIGS. 7, 8, and 9 illustrate some embodiments of an image sensor having a trench isolation structure extending into a back-side surface of a substrate.

FIG. 10 illustrates a top view of an image sensor with an image sensor having a trench isolation structure that includes a partial depth isolation structure and a full depth isolation structure.

FIGS. 11-33 illustrate various views of some embodiments of a method of forming an image sensor having a trench isolation structure having a full depth isolation structure and a partial depth isolation structure with different depths.

FIGS. 34-40 illustrate various cross-sectional views of some other embodiments of a method of forming an image sensor comprising a trench isolation structure having a full depth isolation structure and a partial depth isolation structure with different depths.

FIGS. 41 and 42 illustrate flow diagrams of some embodiments of a method of forming an image sensor with an isolation structure having a full depth isolation structure and a partial depth isolation structure with different depths.

FIGS. 43-48 illustrate various views of some embodiments of a method of forming an image sensor having a trench isolation structure having a full depth isolation structure with one or more tab structures.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Image sensors (e.g., semiconductor image sensors (CISs)) may include a plurality of pixel sensors disposed on a substrate. The pixel sensors include photodetectors that are configured to convert energy from a radiation source (e.g., light, infrared radiation, x-rays, etc.) into electrical current. In an effort to scale down the image sensor, the pixel sensors have a shared pixel layout where a plurality of photodetectors share a floating diffusion node that is disposed at a crossroad of the plurality of photodetectors. However, as the image sensor is scaled, the photodetectors are disposed closer in proximity to one another, which can increase cross-talk and noise between the pixel sensors. To mitigate noise, the photodetectors are separated from one another by one or more isolation structures that are configured to mitigate electrical or photonic cross-talk between photodetectors. In some aspects, the one or more isolation structures are formed from one or more of a back-side or a front-side of the substrate containing the photodetectors and floating diffusion node.

For example, a partial deep trench isolation (P-DTI) structure can be formed over the floating diffusion node and a full deep trench isolation (F-DTI) structure can be formed through the substrate surrounding the floating diffusion node and between adjacent photodetectors. The P-DTI structure and the F-DTI structure can be formed from the back-side or the front-side of the substrate. However, the processing of the P-DTI and F-DTI structures on the same substrate requires precise control over several parameters. Notably, ensuring accurate alignment of the trenches in which the P-DTI and the F-DTI structures are formed in is critical. Misalignment of the trenches can lead to ineffective isolation and consequently increase electronic noise and diminish performance of the image sensor. Additionally, controlling the depth and profile of these trenches is complex as pixel sizes in the image sensor shrinks. Image miniaturization exacerbates the fabrication challenges due to the reduced spatial margins for error where small misalignments can have pronounced negative impact on the image sensor's performance. Therefore, the development of image sensors and associated methods to reliably and accurately fabricate these isolation structures, particularly in the context of small pixel sizes, is important in advancing image sensor technology.

Various aspects of the present disclosure are directed towards an image sensor that includes a multi-depth trench isolation structure having a partial depth isolation structure and a full depth isolation structure within a substrate. The image sensor can include a plurality of pixel sensors disposed on the substrate. The pixel sensors respectively comprise a plurality of photodetectors disposed within the substrate and surrounded by the multi-depth isolation grid. The pixel sensors each have a shared pixel layout such that a floating diffusion node is disposed at a crossroad or a center of the plurality of photodetectors. The partial depth isolation structure is arranged at the crossroad of the photodetectors over the floating diffusion node. The full depth isolation structure surrounds the photodetectors at peripheries offset from the partial depth isolation structure and has a first depth. The partial depth isolation structure has a second depth less than the first depth. In some embodiments, the first depth is equal to or greater than a full depth (i.e., a full thickness or height) of the substrate, whereas the second depth is less than the full depth of the substrate. The partial depth isolation structure mitigates leakage from the floating diffusion node and facilitates each pixel sensor having the shared pixel layout by accommodating space in the substrate for the floating diffusion node. Further, the full depth isolation structure spanning the full depth of the substrate facilitates better electrical and optical isolation between adjacent photodetectors and neighboring pixel sensors. The arrangement of the partial depth isolation structure and the full depth isolation structure forms a grid that effectively isolates the photodetectors, thereby decreasing crosstalk and noise in the image sensor. Accordingly, an overall performance of the image sensor is increased.

In some examples discussed herein, the multi-depth trench isolation structure that includes the full depth and partial depth isolation structures are formed according to a two-step process. First, the full depth isolation structure is formed extending from the front-side of the substrate between the photodetectors and adjacent to the floating diffusion node. Second, a partial depth isolation structure is formed extending from the back-side of the substrate between sidewalls of the full depth isolation structure and over the floating diffusion node. The partial depth isolation structure is formed with a primary etch followed by an extension etch. A partial depth isolation opening is formed between sidewalls of the full depth isolation structure from a back-side surface of the substrate according to a mask and the primary etch. As the mask may be formed on the back-side surface of the substrate with an alignment or registration error, the controlled extension etch can be applied to the partial depth isolation opening to extend the partial depth isolation opening to the full depth isolation structure sidewalls without over-etching into other regions of the substrate. The partial depth isolation opening is subsequently filled to form the partial depth isolation structure. Thus, the partial depth isolation opening is formed with a controlled profile that can accommodate misalignment during the fabrication process.

The resulting multi-depth trench isolation structure increases electrical and optical isolation of the image sensor while accommodating space for the floating diffusion node in the substrate. Furthermore, front-side and back-side substrate processing with depth and profile control is achieved for design flexibility in realizing the multi-depth trench isolation structure.

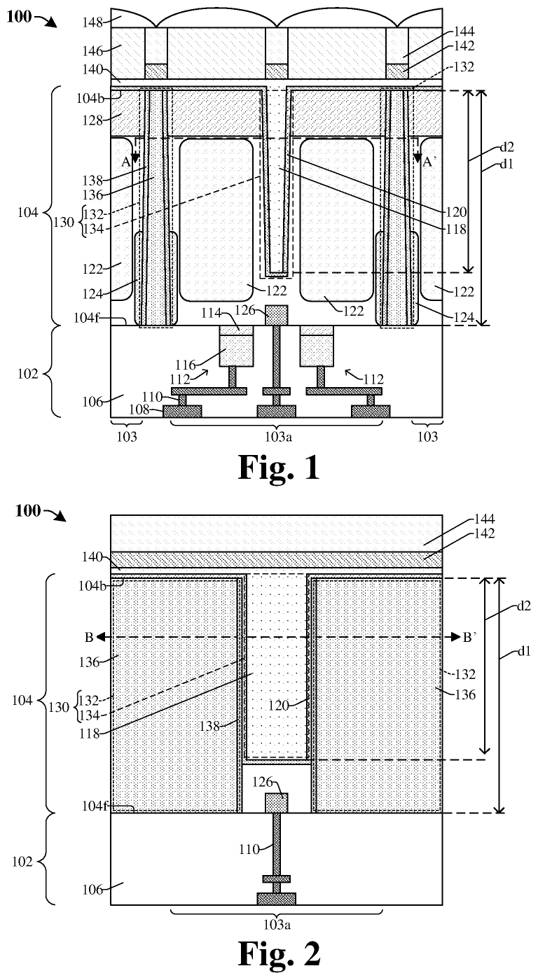

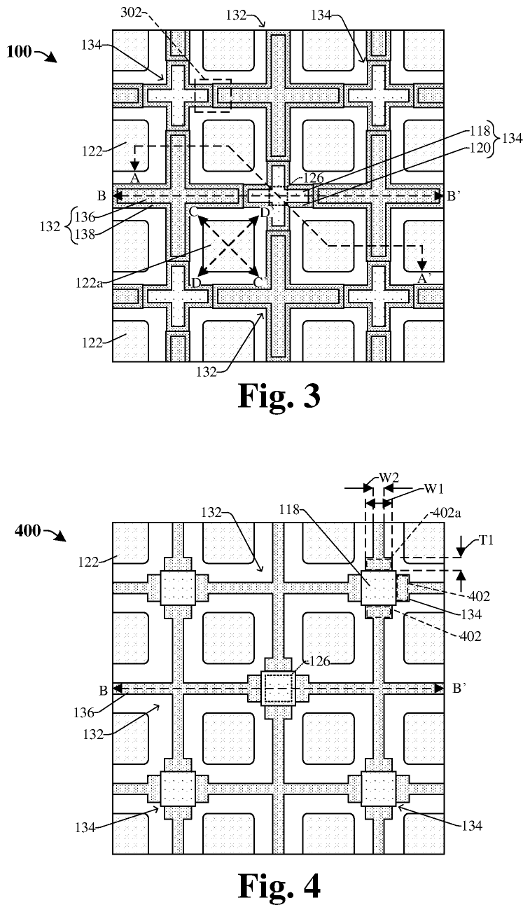

FIGS. 1-3 illustrate various views of some embodiments of an image sensor 100 including a trench isolation structure 130 having a full depth isolation structure 132 and a partial depth isolation structure 134. FIG. 1 illustrates a cross-sectional view of some embodiments of the image sensor 100 taken along line A-A′ of FIG. 3. FIG. 2 illustrates a cross-sectional view of some embodiments of the image sensor 100 taken along line B-B′ of FIG. 3. FIG. 3 illustrates a top view of some embodiments of the image sensor 100.

Referring now to FIGS. 1-3 concurrently, the image sensor 100 has a plurality of pixel sensors 103 on a substrate 104. An interconnect structure 102 is disposed along a front-side surface 104f of the substrate 104. In some embodiments, the substrate 104 comprises a semiconductor body (e.g., bulk silicon) and/or has a first doping type (e.g., p-type). The interconnect structure 102 comprises an interconnect dielectric structure 106, a plurality of conductive wires 108, and a plurality of conductive vias 110. A plurality of pixel devices 112 are disposed along the front-side surface 104f of the substrate 104 and the pixel devices 112 are electrically coupled to one another and/or other semiconductor devices (not shown) by way of the plurality of conductive wires and vias 108, 110. The plurality of pixel devices 112 may comprise a gate electrode 116 and a gate dielectric layer 114 disposed between the gate electrode 116 and the front-side surface 104f of the substrate 104.

A plurality of photodetectors 122 are disposed across the substrate 104. The plurality of pixel sensors 103 respectively comprise one or more of the photodetectors 122. For example, the pixel sensors 103 may each comprise fourth photodetectors 122 disposed in a shared pixel layout structure (e.g., a 2×2 shared pixel layout). In other embodiments, the pixel sensors 103 may have a 2×1 layout, a 3×2 layout, or some other suitable layout. The photodetectors 122 may each comprise a second doping type (e.g., n-type) opposite the first doping type (e.g., p-type). In some embodiments, the photodetectors 122 are rectangular in shape and have four sides. In various embodiments, the first doping type is p-type and the second doping type is n-type, or vice versa. In various embodiments, a floating diffusion node 126 is disposed in the substrate 104 along the front-side surface 104f and comprises the second doping type (e.g., n-type). The floating diffusion node 126 may be disposed at a center or a crossroad of a corresponding pixel sensor 103 or at a center of a group of adjacent photodetectors (e.g., disposed at a center of a 2×2 or 4×4 array of photodetectors). As such, the pixel sensors 103 may, for example, have a shared pixel layout. The plurality of photodetectors 122 are configured to absorb incident light (e.g., photons) and generate respective electrical signals corresponding to the incident light. In such embodiments, the plurality of photodetectors 122 may generate electron-hole pairs from the incident light. In various embodiments, the pixel devices 112 may be configured to conduct readout of the generated electrical signals from the plurality of photodetectors 122. For example, the pixel devices 112 may comprise one or more transfer transistors configured to selectively form a conductive channel in the substrate 104 between the floating diffusion node 126 and adjacent photodetectors to transfer accumulated charge (e.g., via absorbing incident radiation) in the photodetectors 122 to the floating diffusion node 126.

A trench isolation structure 130 is disposed within the substrate 104 and comprises a full depth isolation structure 132 and a partial depth isolation structure 134. In some embodiments, the full depth isolation structure 132 extends from the front-side surface 104f to a back-side surface 104b of the substrate 104 and the partial depth isolation structure 134 extends into the substrate 104 from the back-side surface 104b. The full depth isolation structure 132 has a first depth d1 that is greater than a second depth d2 of the partial depth isolation structure 134. In various embodiments, the first depth d1 is equal to or greater than a full depth (i.e., a height or thickness) of the substrate 104 and the second depth d2 is less than the full depth of the substrate 104. In some embodiments the trench isolation structure 130 is referred to as a dual depth isolation structure, or a mixed depth trench isolation structure.

In various embodiments, a deep well region 128 is disposed on the back-side surface 104b of the substrate 104 and comprises the second doping type (e.g., n-type) with a lower doping concentration than the plurality of photodetectors 122. In some embodiments, the deep well region 128 is configured to absorb incident light (e.g., photons) at a location above each photodetector and generate electron-hole pairs from the incident light that may, for example, be transferred to a corresponding photodetector thereby increasing a quantum efficiency (QE) of each photodetector. By virtue of the trench isolation structure 130 laterally enclosing the plurality of photodetectors 122 and being disposed between adjacent photodetectors 122, segments of the deep well region 128 over each photodetector 122 are isolated from one another. Therefore, the trench isolation structure 130 further increases optical and/or electrical isolation for each photodetector (e.g., further decreasing cross-talk in the image sensor). In further embodiments, a doping concentration of the plurality of photodetectors 122 is within a range of about 10¹³ to 10¹⁴ atoms/cm³, or another suitable value. In some embodiments, a doping concentration of the deep well region 128 is within a range of about 10¹² to 10¹⁴ atoms/cm³, or another suitable value.

In some embodiments, a shallow well region 124 is disposed along sidewalls of the full depth isolation structure 132 within the substrate 104 and is configured to increase electrical isolation between adjacent photodetectors of the plurality of photodetectors 122. In various embodiments, the shallow well region 124 is ring-shaped when viewed from a top view and continuously wraps around the plurality of photodetectors 122 of a first pixel sensor 103a. The shallow well region 124 is laterally offset from the partial depth isolation structure 134 and extends from a point vertically above a bottom surface of the partial depth isolation structure 134 to a point aligned with a bottom surface of the full depth isolation structure 132. The shallow well region 124 comprises the first doping type (e.g., p-type).

An upper dielectric layer 140 is disposed along the back-side surface 104b of the substrate 104. In some embodiments, the upper dielectric layer 140 is an extension of the partial depth isolation structure 134 and covers the full depth isolation structure 132 and the substrate 104. In various embodiments the upper dielectric layer 140 is configured as and/or referred to as a passivation layer. A conductive grid structure 142 overlies the upper dielectric layer 140 and a dielectric grid structure 144 overlies the conductive grid structure 142. The conductive grid structure 142 and the dielectric grid structure 144 comprise sidewalls that define a plurality of openings directly overlying a corresponding photodetector in the plurality of photodetectors 122. In various embodiments, the conductive grid structure 142 comprises one or more metal layers that is/are configured to reduce cross-talk between adjacent photodetectors in the plurality of photodetectors 122, thereby increasing optical isolation of the image sensor. In addition, the dielectric grid structure 144 is configured to direct light to the plurality of photodetectors 122 by total internal reflection such that cross-talk is further reduced and the QE of the plurality of photodetectors 122 is increased. A plurality of light filters 146 are disposed in the plurality of openings defined by the sidewalls of the conductive grid structure 142 and the dielectric grid structure 144. The light filters 146 are configured to transmit specific wavelengths of incident light while blocking other wavelengths of incident light. Further, a plurality of micro-lenses 148 overlies the light filters 146 and are configured to focus the incident light towards the photodetectors 122.

The full depth isolation structure 132 extends from the front-side surface 104f of the substrate to the back-side surface 104b of the substrate 104. In some embodiments, the full depth isolation structure 132 is referred to as a first isolation structure, a deep trench isolation (DTI) structure, or a full DTI (F-DTI) structure. The full depth isolation structure 132 extends substantially parallel with a first side and a second side of the four sides of the photodetector. A bottom surface of the full depth isolation structure 132 has a first width and a top surface of the full depth isolation structure 132 has a second width that is less than the first width. The full depth isolation structure 132 comprises a first trench fill layer 136 and a first liner 138. The first trench fill layer 136 is separated from the substrate 104 by the first liner 138, where the first liner 138 is disposed along outer sidewalls of the first trench fill layer 136.

The partial depth isolation structure 134 extends from the back-side surface 104b of the substrate to the front-side surface 104f of the substrate 104. In some embodiments, the partial depth isolation structure 134 is referred to as a second isolation structure, a DTI structure, a partial DTI (P-DTI) structure, or a partial back-side DTI (P-BDTI). The partial depth isolation structure 134 extends substantially parallel with the first and second sides of the photodetector. The partial depth isolation structure 134 has a first width vertically aligned with the back-side surface 104b of the substrate 104 and a bottom surface of the partial depth isolation structure 134 has a second width that is less than the first width. As such, in some embodiments, the first width of the partial depth isolation structure 134 is greater than a width of the top surface of the full depth isolation structure 132. In further embodiments, the second width of the partial depth isolation structure 134 is less than a width of the bottom surface of the full depth isolation structure 132. In some embodiments, the partial depth isolation structure 134 comprises a second trench fill layer 118 and a second liner 120. The second trench fill layer 118 is separated from the substrate 104 by the second liner 120, where the second liner 120 is disposed along outer sidewalls and a bottom surface of the second trench fill layer 118. The second liner 120 is also disposed along the top surfaces of the first trench fill layer 136 and the first liner 138. In various embodiments, a planarization process is performed into the second liner 120 and the second trench fill layer 118, such that top surfaces of the second liner 120 and the second trench fill layer 118 are coplanar with the back-side surface 104b of the substrate 104 (not shown). In such embodiments, the upper dielectric layer 140 is omitted.

With reference to the cross-sectional view of FIG. 2, in some embodiments, the second trench fill layer 118 is separated from the first trench fill layer 136 by the second liner 120 and the first liner 138. The partial depth isolation structure 134 is aligned over the floating diffusion node 126 where the second trench fill layer 118 is separated from the floating diffusion node by the substrate 104 and the second liner 120.

In some embodiments, the first trench fill layer 136 and the second trench fill layer 118 are the same material. In other embodiments, the first trench fill layer 136 and the second trench fill layer 118 comprise different materials. The first trench fill layer 136 and the second trench fill layer 118 can be or comprise an oxide, such as silicon dioxide or a high-k dielectric material. In some embodiments, the first liner 138 and the second liner 120 are the same material or comprise different materials. The first liner 138 and the second liner 120 can be or comprise an oxide or a high-k dielectric material.

The partial depth isolation structure 134 is disposed over the floating diffusion node 126 and the full depth isolation structure 132 extends laterally from the partial depth isolation structure 134 between the plurality of photodetectors 122. The full depth isolation structure 132 has the first depth d1 and the partial depth isolation structure 134 has the second depth d2 that is less than the first depth d1. As such, the trench isolation structure 130 has a grid structure when viewed from above that includes the partial depth isolation structure 134 over floating diffusion nodes 126 dispersed amongst the image sensor 100 and the full depth isolation structure 132 extending between the photodetectors 122 (e.g., see FIG. 3). Furthermore, as seen from the top view 300, the full depth isolation structure 132 and the partial depth isolation structure 134 together form at least a linear grid segment 302 of the trench isolation structure 130.

Each photodetector of the plurality of photodetectors 122 is laterally surrounded on all sides by portions of the full depth isolation structure 132 and portions of the partial depth isolation structure 134. For example, as seen in the top view of FIG. 3, a first photodetector 122a has a first pair of edges that are opposite from one another about a line C-C′, and a second pair of edges that are opposite from one another about a line D-D′, where the line C-C′ and the line D-D′ are rotated 90 degrees relative to one another. The first pair of edges face the full depth isolation structure 132 along the line C-C′ and the second pair of edges face the partial depth isolation structure 134 along the line D-D′. Furthermore, adjacent photodetectors of the plurality of photodetectors 122 are laterally spaced from one another separated by both the full depth isolation structure 132 and the partial depth isolation structure 134.

The configuration of the trench isolation structure 130 provides enhanced performance for the image sensor 100. The full depth isolation structure 132 provides isolation between the plurality of photodetectors 122 by spanning the full depth of the substrate 104. However, since the floating diffusion node 126 is disposed within the substrate 104 in the shared pixel layout, the full depth isolation structure 132 being disposed over the floating diffusion node 126 would damage the floating diffusion node 126 and/or prevent the pixel sensors 103 from having the shared pixel layout. To accommodate the floating diffusion node 126 and still provide electrical and photonic isolation between the plurality of photodetectors 122, the partial depth isolation structure 134 is disposed over the floating diffusion node 126. As such, different depth isolation structures are utilized to enhance image sensor 100 performance. Furthermore, front-side and back-side processing of the substrate 104 is leveraged to form the trench isolation structure 130 providing design flexibility.

FIG. 4 illustrates a top view of an image sensor 400 with a full depth isolation structure 132 that includes one or more tab structures 402 surrounding a corresponding partial depth isolation structure 134. The top view of FIG. 4 provides some other embodiments of the image sensor of FIGS. 1-3, where the first and second liners (138, 120 of FIGS. 1-3) are omitted and the full depth isolation structure 132 is defined by the first trench fill layer 136 and the partial depth isolation structure 134 is defined by the second trench fill layer 118. In various embodiments, the first trench fill layer 136 contacts the second trench fill layer 118. In various embodiments, the full depth isolation structure 132 comprises the first trench fill layer 136 surrounded by the first liner 138 (of FIGS. 1-3) and the partial depth isolation structure 134 comprises the second trench fill layer 118 surrounded by the first liner 138 (of FIGS. 1-3). In other embodiments, the first liner 138 is omitted.

In some embodiments, the full depth isolation structure 132 comprises tab structures 402 at an interface between the full depth isolation structure 132 and the partial depth isolation structure 134. Specifically, each tab structure 402 is defined by a first width W1 that is the same as or substantially the same as a width of an adjacent surface of the partial depth isolation structure 134. Further, the tab structures 402 have a thickness T1 defined along the adjacent surface of the partial depth isolation structure 134. Elongated segments of the full depth isolation structure 132 extend from each tab structure 402 where the elongated segments of the full depth isolation structure 132 each have a second width W2 that is less than the first width W1. As such, outer sidewalls of the partial depth isolation structure 134 are laterally surrounded by the full depth isolation structure 132. In various embodiments, the partial depth isolation structure 134 is square shaped when viewed in top view and the full depth isolation structure 132 is cross shaped.

As such, the first trench fill layer 136 and the second trench fill layer 118 directly contact at an interface along outer sidewalls of the second trench fill layer 118. In yet further embodiments, the first liner (138 of FIGS. 1-3) is disposed around an outer perimeter of the first trench fill layer 136 and may be disposed between the first trench fill layer 136 and the second trench fill layer 118.

FIG. 5 illustrates a cross-sectional view of some embodiments of the image sensor 400 of FIG. 4 taken along the line B-B′ of FIG. 4. FIG. 5 shows the second trench fill layer 118 of the partial depth isolation structure 134 directly contacting the first trench fill layer 136 of the full depth isolation structure 132. It is understood that one or more alternative features of FIGS. 4-5 can apply also to FIGS. 1-3 and vice-versa. For example, FIGS. 1-3 can include the tab structure 402 of FIG. 4 and or omit one or more of the first liner 138 or second liner 120 as shown in FIGS. 4-5, or FIGS. 4-5 can include the first liner 138 or second liner 120 of FIGS. 1-3.

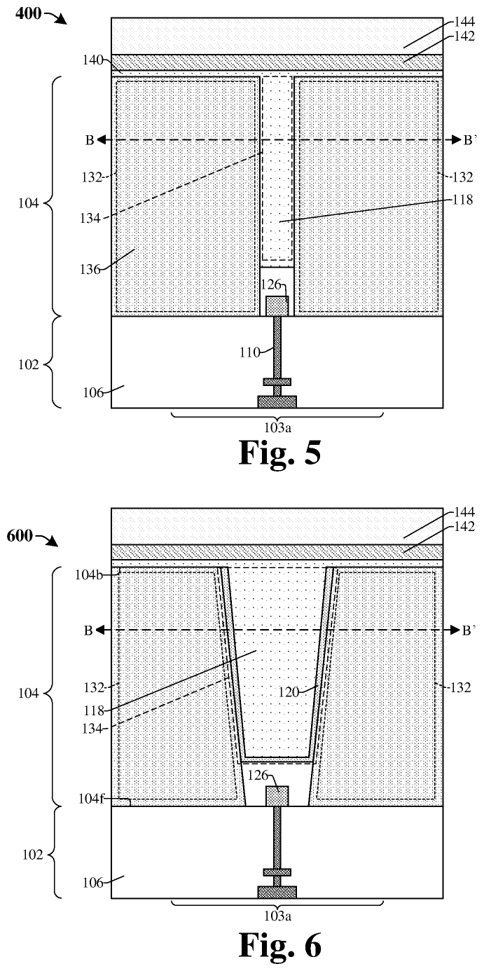

FIG. 6 illustrates a cross-sectional view of some embodiments of an image sensor 600 corresponding to some other embodiments of the image sensor 400 of FIG. 5, where the partial depth isolation structure 134 has a wedge shape. In various embodiments, the cross-sectional view of FIG. 6 is taken along the line B-B′ of FIG. 4. In some embodiments, a width of the partial depth isolation structure 134 aligned with the back-side surface 104b of the substrate 104 is wider than a bottom surface of the partial depth isolation structure 134. The second liner 120 is disposed along sidewalls and the bottom surface of the second trench fill layer 118. Inner opposing sidewalls of the full depth isolation structure 132 that laterally surround the floating diffusion node 126 extend away from one another at the back-side surface 104b of the substrate 104 relative to the front-side surface 104f of the substrate. FIG. 6 shows additional alternative embodiments of FIG. 2 where the first liner 138 is omitted. It is understood that alternative features of FIG. 6 can be included in FIGS. 2 and 5, and vice-versa.

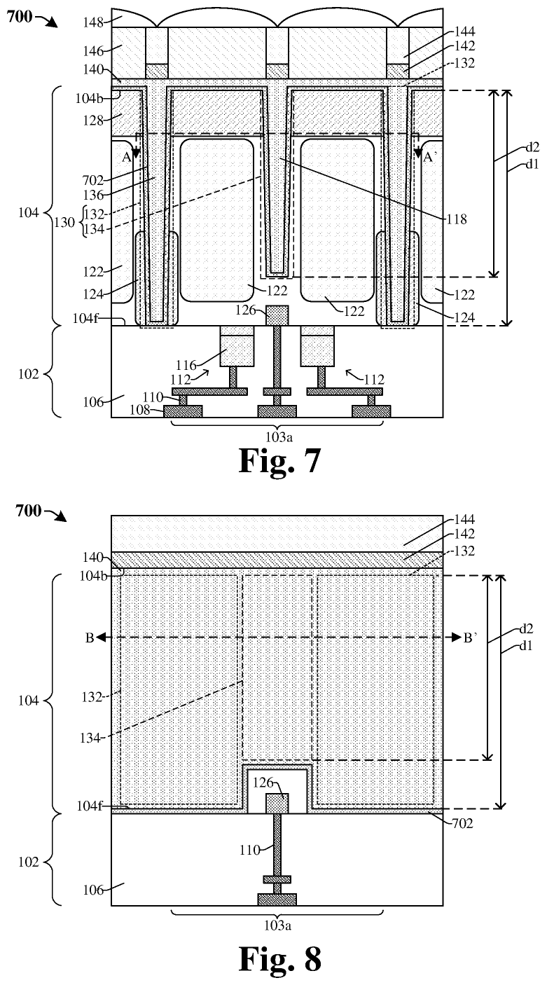

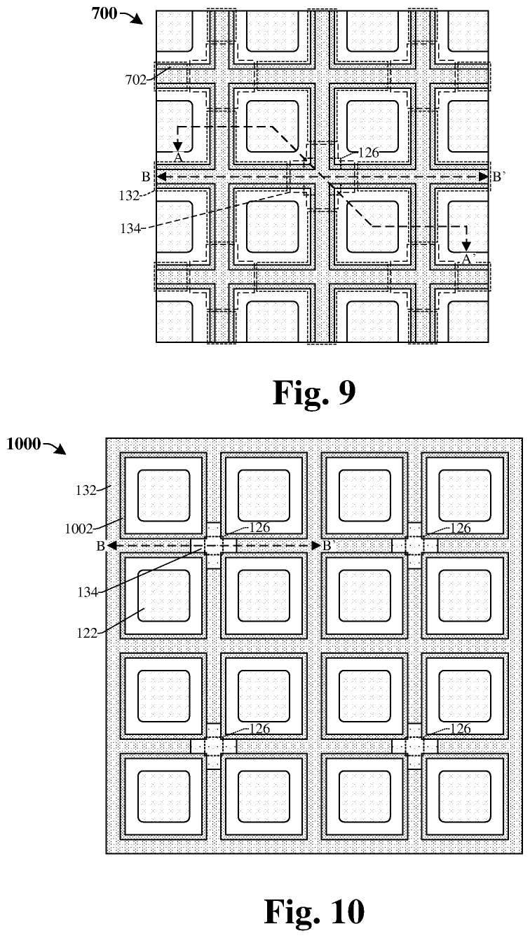

FIGS. 7-9 illustrate various views of some embodiments of an image sensor 700 with a dual depth isolation structure extending into a back-side surface 104b of a substrate 104. FIG. 7 illustrates a cross-sectional view of some embodiments of the image sensor 700 taken along line A-A′ of FIG. 9. FIG. 8 illustrates a cross-sectional view of some embodiments of the image sensor 700 taken along line B-B′ of FIG. 9. FIG. 9 illustrates a top view of some embodiments of the image sensor 700. Referring now to FIGS. 7-9 concurrently.

Where the full depth isolation structure 132 extends from the back-side surface 104b of the substrate to the front-side surface 104f of the substrate, the full depth isolation structure 132 can be referred to as a full back-side DTI (F-BDTI) structure. The image sensor 700 has a full depth isolation structure 132 that is a F-BDTI structure and is continuously connected to the partial depth isolation structure 134 that is a P-BDTI structure. A dielectric liner 702 is disposed along sidewalls and bottom surfaces of the full depth isolation structure 132 and the partial depth isolation structure 134 as viewed from the cross-sectional view at the line A-A′ (FIG. 7).

As seen in the cross-sectional view at the line B-B′ (e.g., FIG. 8), the full depth isolation structure 132 and the partial depth isolation structure 134 are connected as a continuous structure. The dielectric liner 702 is disposed along the bottom surface of the full depth isolation structure 132 and the partial depth isolation structure 134. As such, the dielectric liner 702 separates the trench isolation structure 130 from the interconnect structure 102. Furthermore, the dielectric liner 702 is disposed between the partial depth isolation structure 134 and a top of the floating diffusion node 126. Image sensor 700 has the benefit of a trench isolation structure 130 that is continuous thereby avoiding processing defects of the full depth isolation structure 132 and partial depth isolation structure 134 formed in different processing steps thus improving isolation and photodetector performance.

FIG. 10 illustrates a top view of some other embodiments of an image sensor 1000 with alternative features of a dual depth isolation structure. FIG. 10 shows arrays of four photodetectors of the plurality of photodetectors 122 each surrounding a corresponding floating diffusion node 126. Each array of four photodetectors is laterally enclosed by the full depth isolation structure 132, and a liner 1002 is disposed along sidewalls of the full depth isolation structure 132 and the partial depth isolation structure 134. The partial depth isolation structure 134, that may be configured as a P-BDTI structure, is disposed over the floating diffusion node 126. The full depth isolation structure 132, may be a F-FDTI structure, and extends from outer sidewalls of the partial depth isolation structure 134 and between the array of four photodetectors. A cross-sectional view at line B-B′ of FIG. 10 is analogous to the image sensor 400 of FIG. 5. As each array of four photodetectors of the plurality of photodetectors 122 are fully encompassed by the full depth isolation structure 132, and the sub arrays of four photodetectors have enhanced isolation properties compared to other configurations.

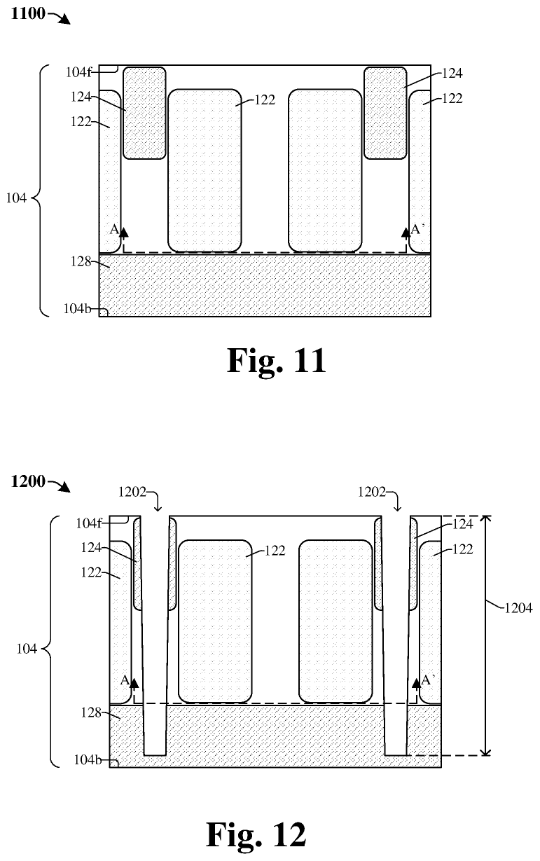

FIGS. 11-33 illustrate various views 1100-3300 of some embodiments of a method for forming an image sensor comprising an isolation structure having a full depth isolation structure and a partial depth isolation structure with different depths. Although the various views 1100-3300 shown in FIGS. 11-33 are described with reference to the method, it will be appreciated that the structures shown in FIGS. 11-33 are not limited to the method but rather may stand alone separate of the method. Furthermore, although FIGS. 11-33 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

As shown in cross-sectional view 1100 of FIG. 11, one or more ion implantation processes is/are performed to form a deep well region 128, a shallow well region 124, and a plurality of photodetectors 122 in a substrate 104. In some embodiments, the substrate 104 may, for example, be or comprise a bulk silicon substrate, monocrystalline silicon, epitaxial silicon, silicon germanium (SiGe), or another suitable semiconductor material and/or comprises a first doping type (e.g., p-type). The substrate 104 comprises a front-side surface 104f that is opposite a back-side surface 104b. Further, the substrate 104 has a first doping type (e.g., p-type). In various embodiments, an ion implantation process comprises: selectively forming a masking layer (not shown) over the front-side surface 104f of the substrate 104; performing a selective ion implantation process according to the masking layer, thereby implanting one or more dopants within the substrate 104; and performing a removal process to remove the masking layer (not shown). In some embodiments, a first ion implantation process may be performed to form the plurality of photodetectors 122 such that the photodetectors 122 comprise a second doping type (e.g., n-type) opposite the first doping type; a second ion implantation process may be performed to form the shallow well region 124 such that the shallow well region 124 comprises the first doping type; and a third ion implantation process may be performed to from the deep well region 128 such that the deep well region 128 comprises the second doping type (e.g., n-type). In various embodiments, the photodetectors 122 have a higher doping concentration than the deep well region 128. In yet further embodiments, the third ion implantation process may be performed without forming a masking layer over the substrate 104.

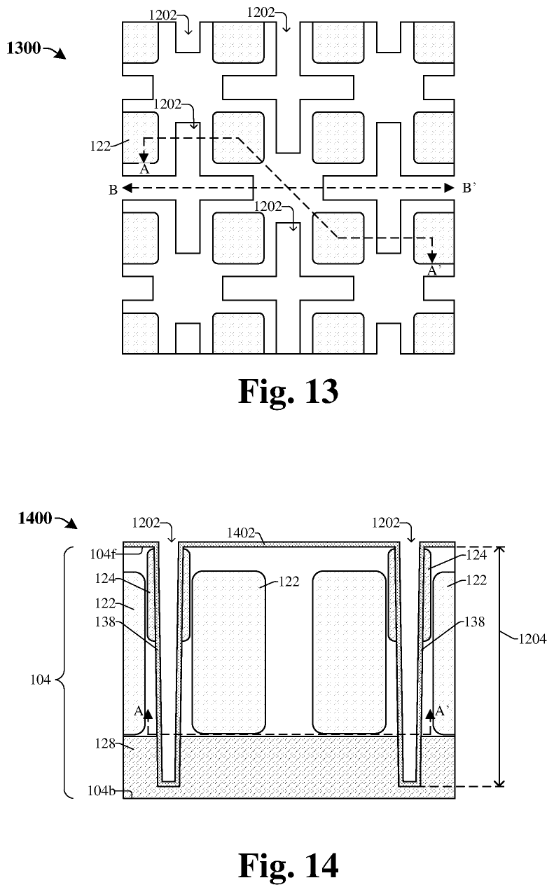

As illustrated in cross-sectional view 1200 of FIG. 12, a patterning process is performed on the front-side surface 104f of the substrate 104 to form a full depth isolation opening 1202 extending into the front-side surface 104f. FIG. 13 illustrates a top view 1300 of some embodiments of the cross-sectional view 1200 of FIG. 12. In some embodiments, the patterning process includes: forming a masking layer (not shown) over the front-side surface 104f of the substrate 104; etching (e.g., by a dry etch process and/or a wet etch process) the substrate 104 according to the masking layer; and removing the masking layer. In some embodiments, the etchant is a reactive ion etching or other plasma etching technique. However, the etching process can introduce physical defects like roughness or pitting in the substrate that can change the electrical properties of the substrate. As such, in some embodiments, a high temperature process can be employed after etching to repair any etching damage. For example, a surface passivation process can be applied to the substrate 104 and full depth isolation opening 1202 and/or additional chemical treatments to stabilize the etched surface and reduce the effects of etching induced damage. In various embodiments, the full depth isolation opening 1202 has a depth 1204 that is less than a full depth (i.e., a height) of the substrate 104. In yet further embodiments, the full depth isolation opening 1202 is formed such that the full depth isolation opening 1202 is ring-shaped when viewed from above and continuously laterally wraps around the plurality of photodetectors 122 (not shown).

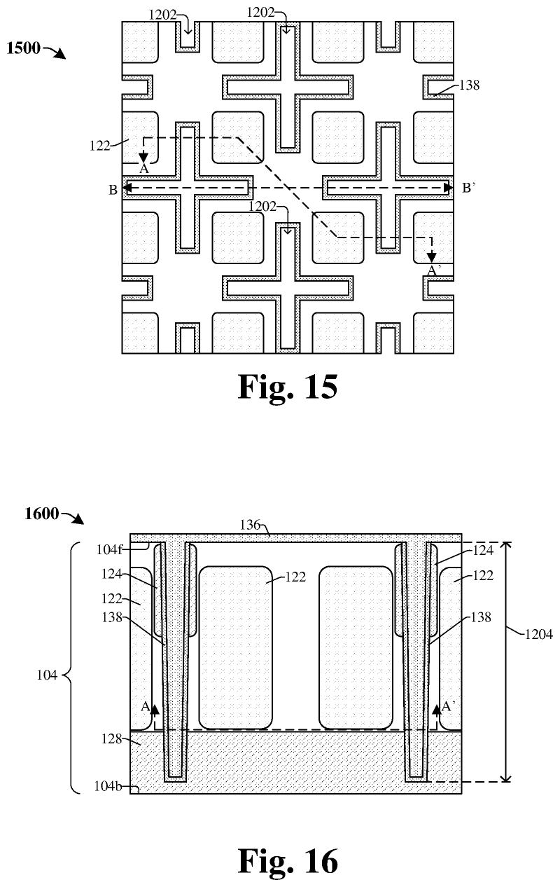

As illustrated in cross-sectional view 1400 of FIG. 14, a first liner layer 1402 is formed within the full depth isolation opening 1202 and over the substrate 104. FIG. 15 illustrates a top view 1500 of some embodiments of the cross-sectional view 1400 of FIG. 14. The first liner layer 1402 is formed over the front-side surface 104f of the substrate and extends into the full depth isolation opening 1202. The first liner layer 1402 is formed by a deposition process. In some embodiments, the first liner layer 1402 is formed by chemical vapor deposition (CVD), plasma enhanced CVD (PECVD), atomic layer deposition (ALD), thermal oxidation, or the like. In some embodiments, the first liner layer 1402 may be or comprise an oxide, such as silicon dioxide, a high-k dielectric, or the like. In some embodiments, after forming the first liner layer 1402, an annealing process is performed. The annealing process can reduce defects in the substrate 104 caused by the etchant that formed the full depth isolation opening 1202.

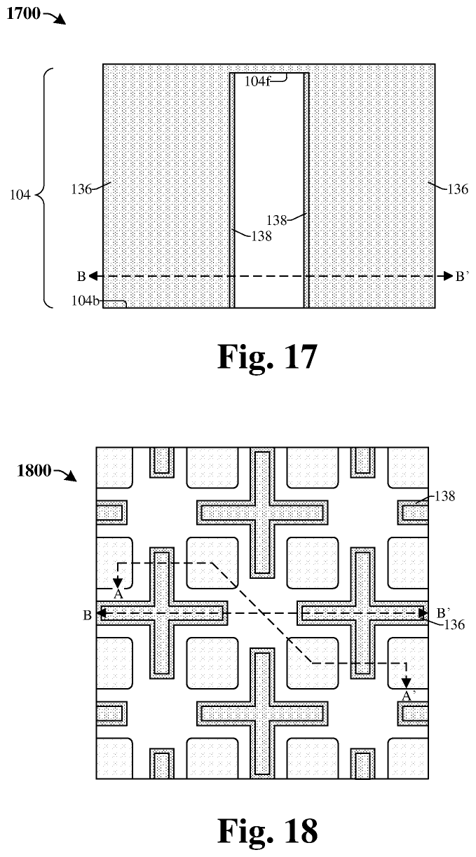

As illustrated in cross-sectional views 1600 and 1700 of FIGS. 16 and 17, a first trench fill layer 136 is formed between inner sidewalls of the first liner 138 and over the front-side surface 104f of the substrate 104. FIG. 18 illustrates a top view 1800 of some embodiments of FIGS. 16 and 17, where the cross-sectional view 1600 of FIG. 16 is taken along the line A-A′ of FIG. 18 and the cross-sectional view 1700 of FIG. 17 is taken along the line B-B′ of FIG. 18. Before forming the first trench fill layer 136, the first liner layer 1402 of FIG. 14 under goes a removal process, like a planarization process. In some embodiments, the removal process applied to the first liner layer 1402 is a chemical mechanical planarization (CMP) process. Thereafter, the first liner layer 1402 is removed from the front-side surface 104f of the substrate 104 thereby forming the first liner 138 within the full depth isolation opening 1202 (of FIG. 14). In some embodiments, the first trench fill layer 136 is formed by a CVD process, a PVD process, an ALD process, or the like. In some embodiments, the full depth trench fill layer may be or comprise an oxide such as silicon dioxide, a high-k dielectric, or the like. It is understood that in some embodiments, the first liner 138 of FIG. 15 is omitted (e.g., see FIGS. 4 and 5) and the full depth trench fill layer is formed between inner sidewalls of the substrate 104 within the full depth isolation opening 1202 of FIG. 14.

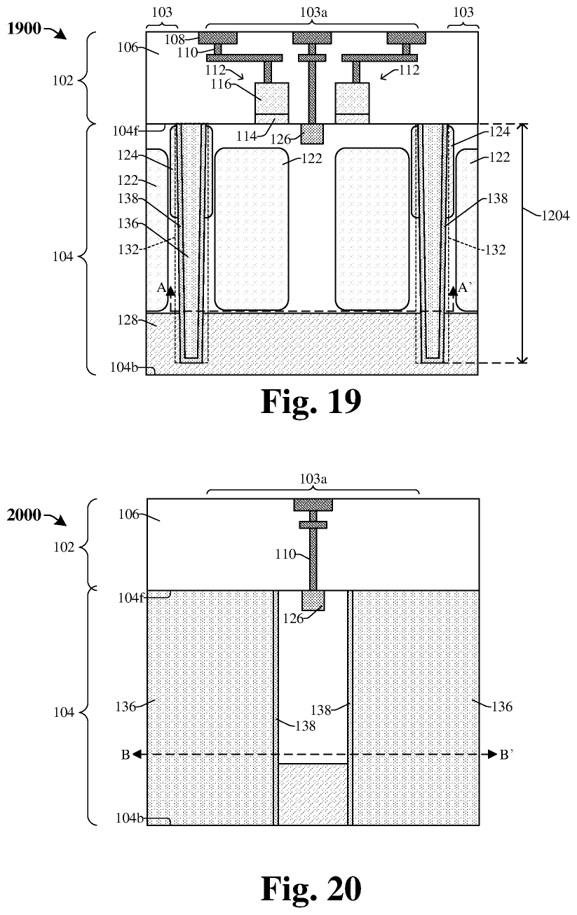

As illustrated in cross-sectional views 1900 and 2000 of FIGS. 19 and 20, a floating diffusion node 126 is formed within the substrate 104, a plurality of pixel devices 112 are formed on the substrate 104, and an interconnect structure 102 is formed along the front-side surface 104f of the substrate 104. This, in part, defines a plurality of pixel sensors 103 on the substrate 104, where each pixel sensor 103 comprises a plurality of photodetectors 122 around a floating diffusion node 126 and a plurality of pixel devices 112 on the substrate 104. A removal process, such as a planarization process, is performed on the substrate 104 of FIGS. 16-18 to form the first trench fill layer 136 that has a top surface that is level with the front-side surface 104f of the substrate 104. The floating diffusion node 126 is formed according to a mask (not shown) and a doping process on the front-side surface 104f of the substrate 104. The floating diffusion node 126 is formed between adjacent photodetectors of the plurality of photodetectors 122. In some embodiments, the floating diffusion node 126 is formed with a second doping type (e.g., n-type) that is different than the doping type of the substrate 104 and the same doping type as the photodetectors 122. The interconnect structure 102 comprises an interconnect dielectric structure 106, a plurality of conductive wires 108, and a plurality of conductive vias 110. In various embodiments, the interconnect dielectric structure 106 may be formed by one or more deposition process(es) such as a PVD process, a CVD process, an ALD process, another suitable growth or deposition process, or any combination of the foregoing. In further embodiments, the plurality of conductive wires 108 and/or the plurality of conductive vias 110 may be formed by one or more deposition process(es), one or more patterning process(es), one or more planarization process(es), or some other suitable process(es).

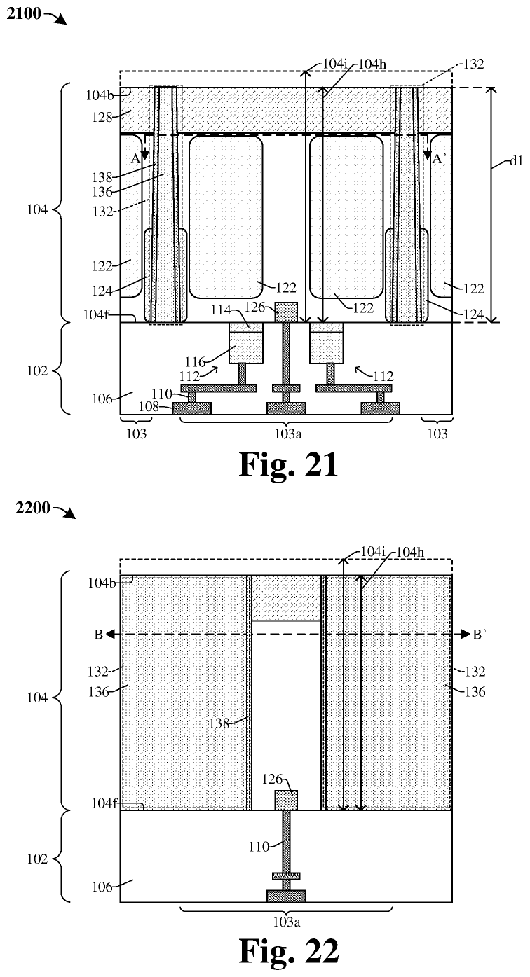

As illustrated in cross-sectional views 2100 and 2200 of FIGS. 21 and 22, the structure of FIGS. 19 and 20 is rotated 180 degrees and a thinning process is performed on the back-side surface 104b of the substrate 104. The thinning process reduces a height of the substrate 104 from an initial substrate height 104i to a height 104h. In some embodiments, the height 104h of the substrate 104 is within a range of about 2 um to about 6 um, within a range of about 2 um to 4 um, within a range of about 4 um to 6 um, or some other suitable value. In further embodiments, the thinning process includes performing a CMP process, a mechanical grinding process, another suitable thinning process, or any combination of the foregoing. In various embodiments, the thinning process removes at least a portion of the deep well region 128 and/or is completed until the first trench fill layer 136 is exposed. After the thinning process, the full depth isolation structure 132 has a first depth d1 that may, for example, be equal to the height 104h (i.e., a full depth) of the substrate 104.

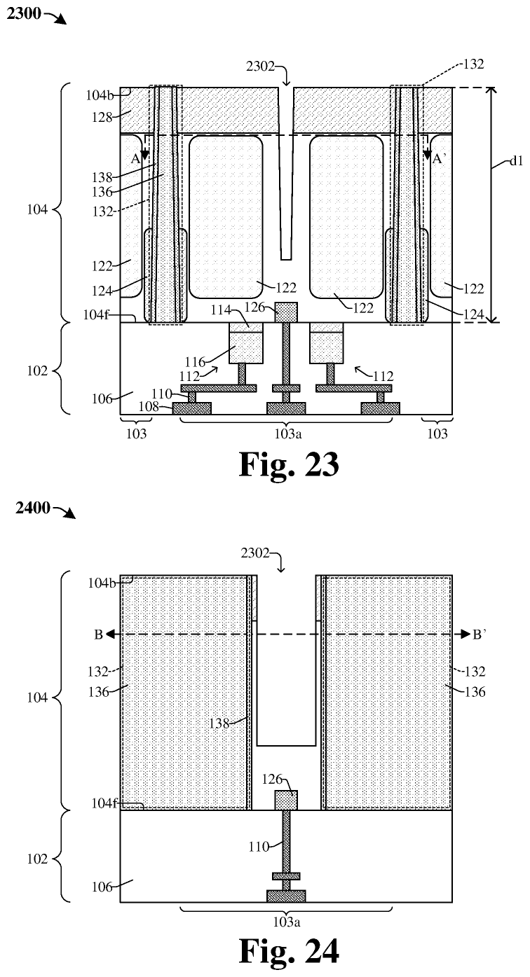

As illustrated in cross-sectional views 2300 and 2400 of FIGS. 23 and 24, a patterning process is performed on the back-side surface 104b of the substrate 104 to form a first partial depth isolation opening 2302 extending into the back-side surface 104b. FIG. 25 illustrates a top view 2500 of some embodiments of FIGS. 23 and 24, where the cross-sectional view 2300 of FIG. 23 is taken along the line A-A′ of FIG. 25 and the cross-sectional view 2400 of FIG. 24 is taken along the line B-B′ of FIG. 25. In some embodiments, the patterning process includes: forming a masking layer (not shown) over the back-side surface 104b of the substrate 104; etching (e.g., by a dry etch process) the substrate 104 according to the masking layer; and removing the masking layer. After the etch, the first partial depth isolation opening 2302 is separated from the full depth isolation structure 132 by the substrate 104 from a top view (e.g., FIG. 25). In some embodiments, the first partial depth isolation opening 2302 is formed such that the first partial depth isolation opening 2302 is cross-shaped when viewed from above and spaced between adjacent photodetectors in the plurality of photodetectors 122 (e.g., FIG. 25). Or alternatively, the first partial depth isolation opening 2302 can be square shaped (e.g., FIG. 4). The first partial depth isolation opening 2302 is formed with a front-side surface that is separated from the floating diffusion node 126 by the substrate 104. In some embodiments, the etch that forms the first partial depth isolation opening 2302 is referred to as a primary etch. In some embodiments, the primary etch is performed with a low bias voltage dry etch such that the substrate 104 is etched in a controlled manner thereby providing precision in the etching profile.

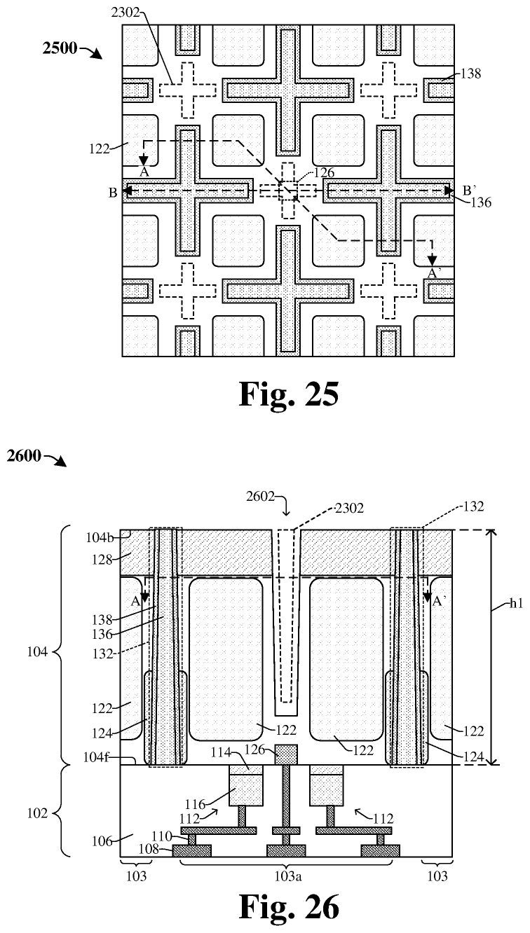

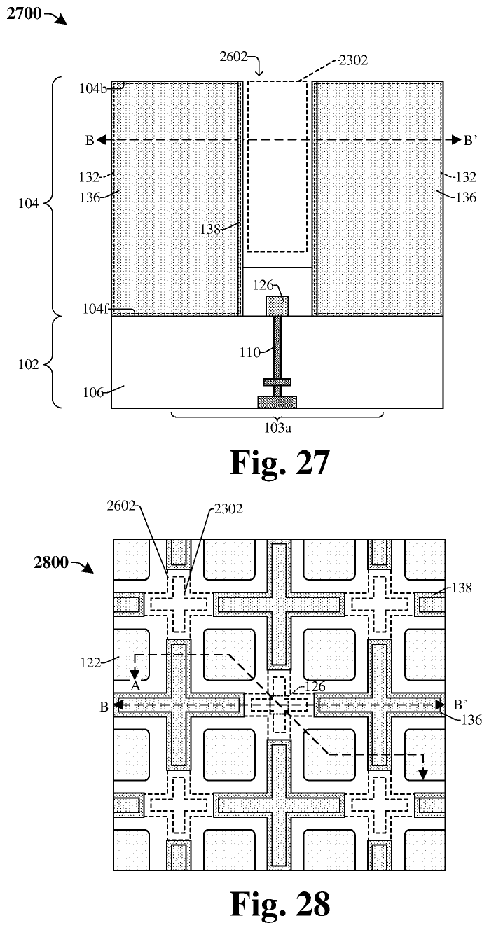

As illustrated in cross-sectional views 2600 and 2700 of FIGS. 26 and 27, a patterning process with a controlled extension etch is performed on the back-side surface 104b of the substrate 104 to form a second partial depth isolation opening 2602 that is an extension of the first partial depth isolation opening 2302. FIG. 28 illustrates a top view 2800 of some embodiments of FIGS. 26 and 27, where the cross-sectional view 2600 of FIG. 26 is taken along the A-A′ of FIG. 28 and the cross-sectional view 2700 of FIG. 27 is taken along the line B-B′ of FIG. 28. In some embodiments, the patterning process includes: forming a masking layer (not shown) over the back-side surface 104b of the substrate 104; performing a controlled extension etch, for example, by a wet etch, on the substrate 104 according to the masking layer over the first partial depth isolation opening 2302; and removing the masking layer. In some embodiments, the controlled extension etch is performed according to a wet etchant that includes a tetramethyl ammonium hydroxide (TMAH) wet etchant. In some embodiments, the substrate 104 is exposed to the TMAH wet etchant for 10 seconds. As such, the first partial depth isolation opening 3602 is extended (e.g., depth and/or width). In some embodiments, the first partial depth isolation opening 2302 is formed with a registration or alignment error. The second partial depth isolation opening 2602 formation process allows for precise control in extending the first partial depth isolation opening 2302 to account for registration errors and realize synergistic design goals for the isolation structure.

In further embodiments the second partial depth isolation opening 2602 is formed by a single etch process that includes forming a masking layer over the substrate 104 and performing a low bias voltage etch (e.g., a dry etch) into the back-side surface 104b of the substrate 104 (not shown). In such embodiments, the low bias voltage etch is performed with a bias voltage lower than that of the etch process of FIG. 12.

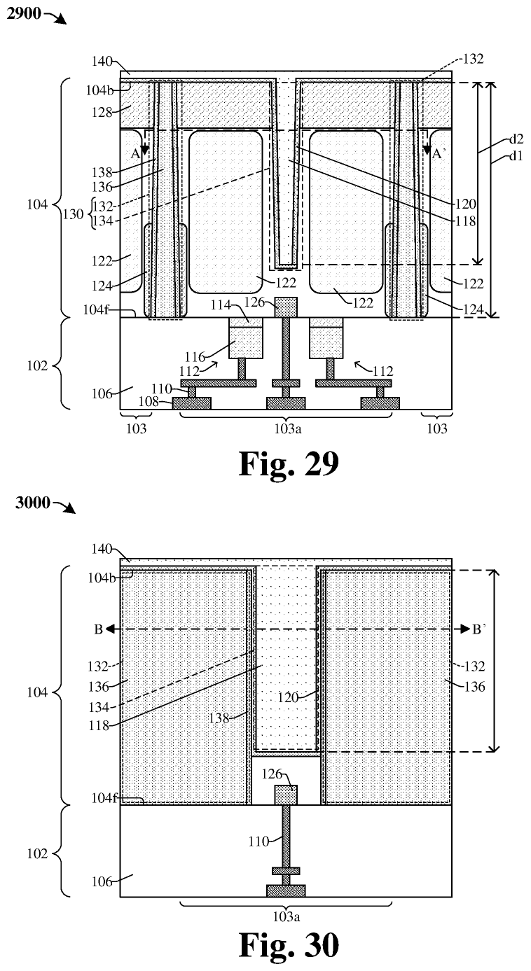

As illustrated in cross-sectional views 2900 and 3000 of FIGS. 29 and 30, deposition processes are performed to form a partial depth isolation structure 134 within the second partial depth isolation opening 2602. FIG. 31 illustrates a top view 3100 of some embodiments of FIGS. 29 and 30, where the cross-sectional view 2900 of FIG. 29 is taken along the line A-A′ of FIG. 31 and the cross-sectional view 3000 of FIG. 30 is taken along the line B-B′ of FIG. 31. Cross-sectional view 3000 of FIG. 30 at the line B-B′ and top view 3100 of FIG. 31 illustrate method steps discussed in accordance with FIG. 29. A second liner 120 is deposited over the substrate 104 covering the full depth isolation structure 132 and lining the second partial depth isolation opening 2602. Subsequently, the back-side surface 104b of the substrate and the second partial depth isolation opening 2602 are filled with a trench dielectric to form a second trench fill layer 118 between inner sidewalls of the second liner and upper dielectric layer 140 over the substrate 104. The second liner 120 and the second trench fill layer 118 form a partial depth isolation structure 134 with a second depth d2 that is less than the first depth d1, where the first depth d1 extends from above the floating diffusion node 126 to the back-side surface 104b of the substrate 104.

In some embodiments, the upper dielectric layer 140 is an extension of the second trench fill layer 118. In some embodiments, the second liner 120, the second trench fill layer 118, and/or the upper dielectric layer 140 are respectively deposited by a CVD process, a PVD process, an ALD process, and/or some other suitable deposition or growth process. In some embodiments, the second liner 120, the second trench fill layer 118, and/or the upper dielectric layer 140 may be or comprise an oxide such as silicon dioxide, a high-k dielectric, or the like. It is understood that in some embodiments, the second liner 120 can be omitted (e.g., see FIGS. 4 and 5) and the second trench fill layer 118 is formed between inner sidewalls of the substrate 104 within the second partial depth isolation opening 2602 of FIGS. 26-28. Where the full depth isolation structure 132 extends from the front-side surface 104f of the substrate 104 to the back-side surface 104b of the substrate 104, the full depth isolation structure 132 can be referred to as a full front-side DTI (F-FDTI) structure.

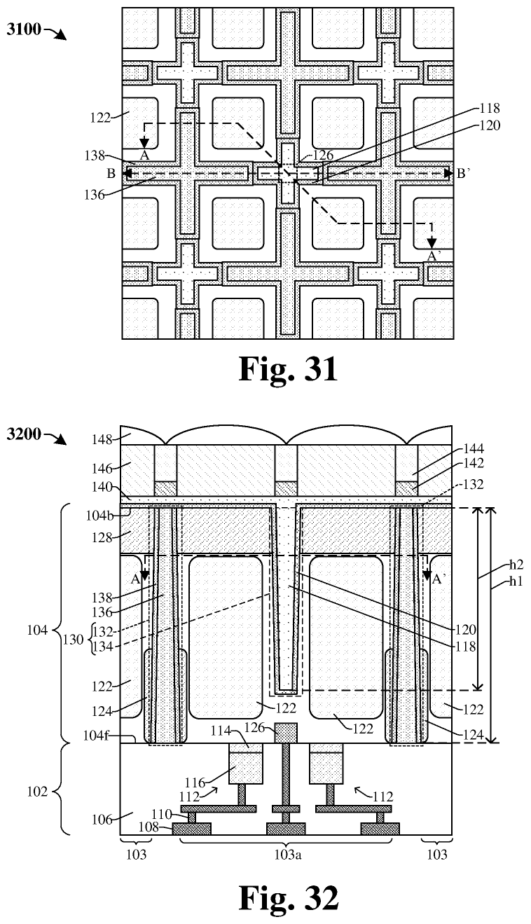

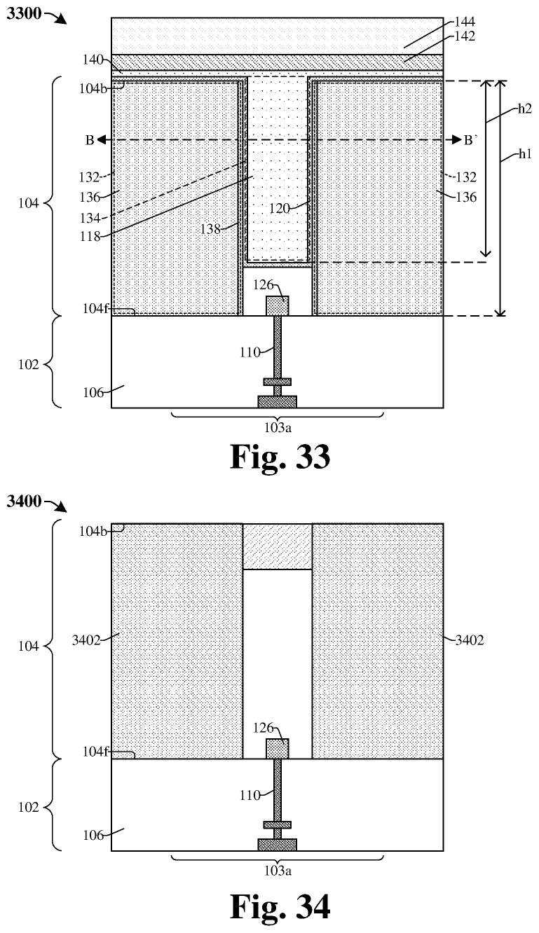

As illustrated in cross-sectional views 3200 and 3300 of FIGS. 32 and 33, a dielectric grid structure 144 is formed over the substrate 104 and a plurality of light filters 146 is formed over the plurality of photodetectors 122 and a plurality of micro-lenses 148 are formed over the plurality of light filters 146. In some embodiments, a process for forming the conductive grid structure 142 and the dielectric grid structure 144 comprises: depositing (e.g., by PVD, CVD, ALD, electroplating, electroless plating, etc.) a metal grid layer over the upper dielectric layer 140; depositing (e.g., by PVD, CVD, ALD, etc.) a dielectric grid layer on the metal grid layer; forming a masking layer (not shown) over the dielectric grid layer; patterning the metal grid layer and the dielectric grid layer according to the masking layer; and performing a removal process to remove the masking layer. In some embodiments, the light filters 146 and the micro-lenses 148 may be deposited by, for example, CVD, PVD, ALD, or some other suitable deposition or growth process.

FIGS. 34-40 illustrate cross-sectional views 3400-4000 of alternative embodiments of a method of forming an image sensor according to the structure of, for example, FIG. 8 where the full depth isolation structure 132 and the partial depth isolation structure 134 are formed from a back-side surface 104b of the substrate 104. FIG. 34 provides other embodiments of FIG. 22 where rather than a first liner 138 and a first trench fill layer 136 formed in the full depth isolation opening 1202 of FIGS. 14-22, a sacrificial dielectric structure 3402 is formed within the full depth isolation opening 1202 of FIG. 12. The sacrificial dielectric structure 3402 can be formed by, for example, a CVD process, a PVD process, an ALD process, or the like. In some embodiments, the sacrificial dielectric structure 3402 can be or comprise an oxide (e.g., silicon dioxide), some other dielectric material, or the like.

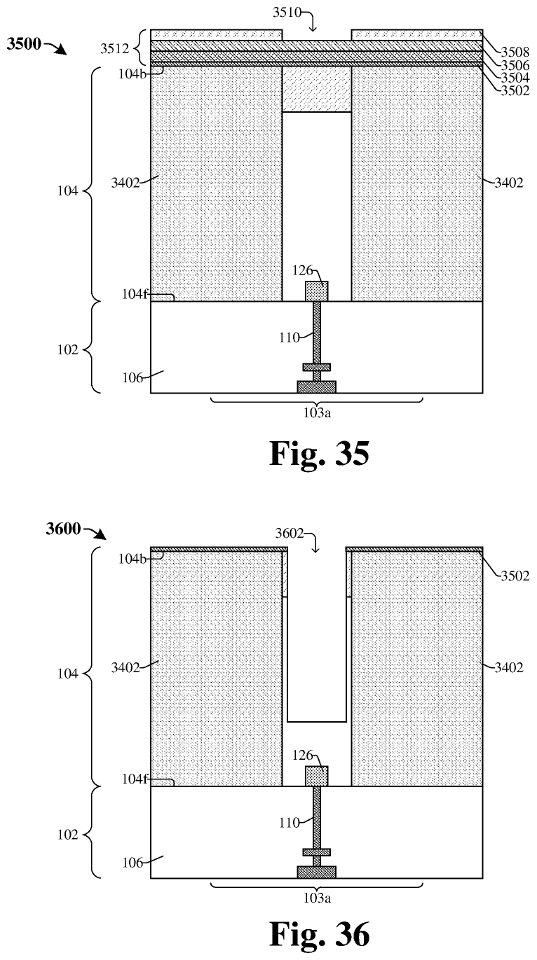

As illustrated in cross-sectional view 3500 of FIG. 35, a multi-layer dielectric structure 3512 is formed over the back-side surface 104b of the substrate 104. The multi-layer dielectric structure 3512 includes a dielectric liner layer 3502, a blocking layer 3504, a middle layer 3506, and a photoresist 3508. The multi-layer dielectric structure 3512 can be formed by one or more deposition processes that includes one or more of a CVD, PVD, or ALD process. The layers of the multi-layer dielectric structure 3512 can be or comprise one or more of an oxide or a dielectric material. In some embodiments, the dielectric liner layer 3502 is formed with a thickness of 50 angstroms (A) to 150 A, the blocking layer 3504 is formed with a thickness of 1000 A to 12000 A, the middle layer 3506 is formed with a thickness of 400 A to 500 A, and the photoresist 3508 is formed with a thickness of 800 A to 1000 A. A removal process (not shown) is performed on the photoresist to form an opening 3510 exposing a back-side surface of the middle layer 3506 aligned over the floating diffusion node 126.

As illustrated in cross-sectional view 3600 of FIG. 36, the back-side surface 104b of the substrate 104 is etched to form a first partial depth isolation opening 3602 extending into the back-side surface 104b. Aspects of FIG. 36 correspond to processing steps discussed in accordance with FIG. 23. In some embodiments, the first partial depth isolation opening 2302 is formed such that the first partial depth isolation opening 3602 is cross-shaped when viewed from above and spaced between adjacent photodetectors in the plurality of photodetectors 122 (e.g., FIG. 25). Or alternatively, the first partial depth isolation opening 3602 can be square shaped (e.g., FIG. 4). The first partial depth isolation opening 3602 is formed with a front-side surface that is separated from the floating diffusion node 126 by the substrate 104. In some embodiments, the etch that forms the first partial depth isolation opening 3602 is referred to as a primary etch. In some embodiments, the primary etch is performed with a low bias voltage such that the substrate 104 is etched in a controlled manner thereby providing precision in the etching profile.

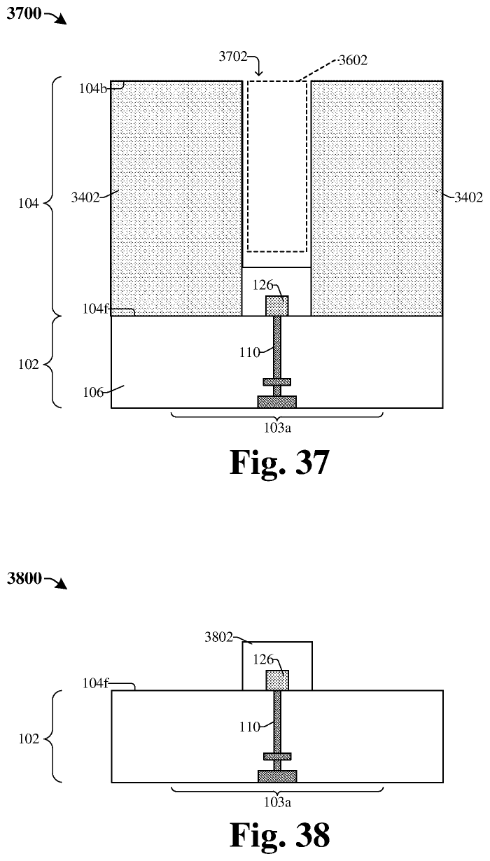

As illustrated in cross-sectional view 3700 of FIG. 37, a patterning process with a controlled extension etch is performed on the back-side surface 104b of the substrate 104 to form a second partial depth isolation opening 3702 that is an extension of the first partial depth isolation opening 3602. The patterning process is performed with the dielectric liner layer 3502 disposed along the back-side surface 104b of the substrate 104 as in FIG. 36. In some embodiments, the controlled extension etch is performed according to a wet etchant that includes a TMAH wet etchant. In some embodiments, the substrate 104 is exposed to the TMAH wet etchant for 10 seconds. As such, the first partial depth isolation opening 3602 is extended. In some embodiments, the first partial depth isolation opening 3602 is formed with a registration or alignment error. The second partial depth isolation opening 3702 formation process allows for precise control in extending the first partial depth isolation opening 3602 to account for registration errors and realize synergistic design goals for the isolation structure.

As illustrated in cross-sectional view 3800 of FIG. 38, a removal process is performed to remove the sacrificial dielectric structure 3402 of FIG. 37. The removal process may include performing a dry etch, a wet etch, or some other suitable process. In some embodiments, the removal process is a wet removal process with a diluted hydrofluoric acid (DHF) etchant. In some embodiments, the sacrificial dielectric structure 3402 is exposed to the DHF etchant for up to 500 to 800 seconds. In other embodiments, the sacrificial dielectric structure 3402 is exposed to the DHF etchant for 550 to 750 seconds. After the removal process, a portion of the substrate 3802 is disposed over and around the floating diffusion node 126, and a front-side surface of the interconnect structure 102 is exposed.

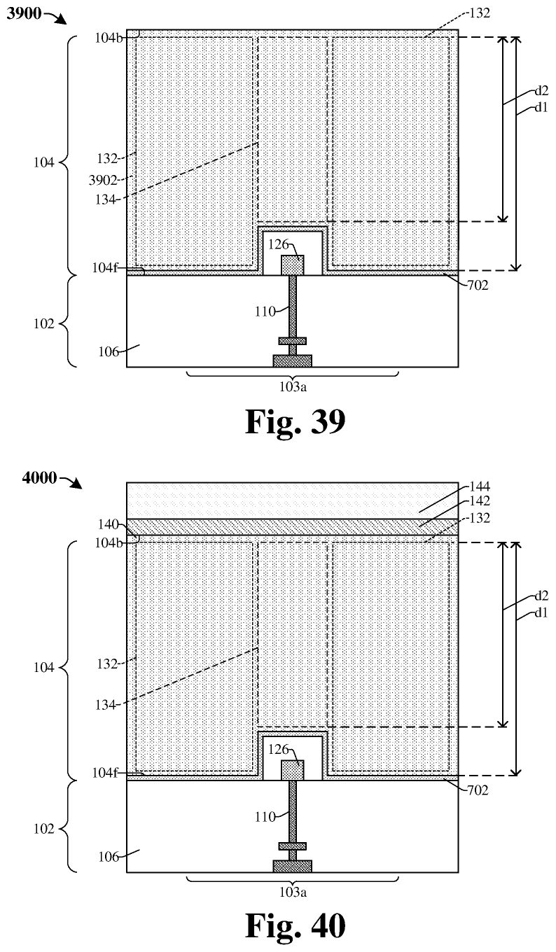

As illustrated in cross-sectional view 3900 of FIG. 39, a dielectric liner 702 is deposited over the substrate 104 and the interconnect structure 102 and a trench fill layer 3902 is deposited over the dielectric liner 702. In some embodiments, the dielectric liner 702 and trench fill layer 3902 are respectively deposited by a CVD process, a PVD process, an ALD process, and/or some other suitable deposition or growth process. The dielectric liner 702 and the trench fill layer 3902 can be or comprise one or more of an oxide or a dielectric material. The trench fill layer 3902 forms a partial depth isolation structure 134 over the floating diffusion node 126 and a full depth isolation structure 132 on adjacent sides of the partial depth isolation structure 134, where the partial depth isolation structure 134 and the full depth isolation structure 132 are a continuous connected structure formed from the back-side of the substrate. Forming the sacrificial dielectric structure 3402 from the front-side of the dielectric aids in precise control over the profile of the trench fill layer 3902 for a dual depth trench structure. Where the full depth isolation structure 132 extends from the back-side surface 104b of the substrate to the front-side surface 104f of the substrate (not shown), the full depth isolation structure 132 can be referred to as a full back-side DTI (F-BDTI) structure.

As illustrated in cross-sectional view 4000 of FIG. 40, a conductive grid structure 142 and a dielectric grid structure 144 are formed over the substrate 104. Further, a plurality of light filters are formed over the plurality of photodetectors and a plurality of micro-lenses are formed over the plurality of light filters (not shown). The aforementioned features are formed as described in accordance with FIGS. 32-33.

While FIGS. 11-40 are shown corresponding to a particular cross-sectional or top view, it is understood that FIGS. 11-40 can be modified according to the description and FIGS. 1-10 and associated cross-sectional or top views. As such, some features from FIGS. 11-40 can be omitted, or additional features added in accordance with FIGS. 1-10.

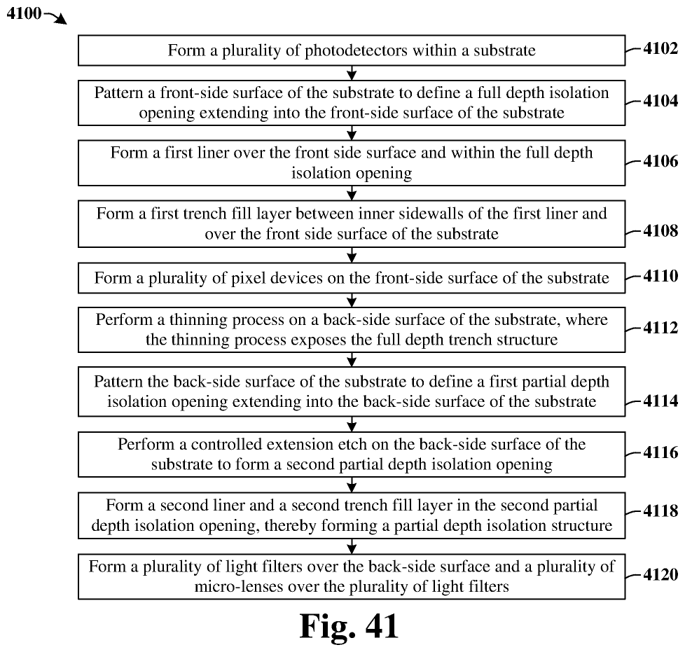

FIG. 41 illustrates some embodiments of a method 4100 of forming an image sensor or semiconductor device comprising an isolation structure having a full depth isolation structure and a partial depth isolation structure with different depths and formed from the front-side and back-side of a substrate according to the present disclosure. Although the method 4100 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 4102, a plurality of photodetectors is formed within a substrate. FIG. 11 illustrates a cross-sectional view 1100 corresponding to some embodiments of act 4102.

At act 4104, a front-side surface of the substrate is patterned to define a full depth isolation opening extending into the front-side surface of the substrate. FIGS. 12-13 illustrate views 1100-1200 corresponding to some embodiments of act 4104.

At act 4106, a first liner is formed over the front-side surface and within the full depth isolation opening. FIGS. 14-15 illustrate views 1400-1500 corresponding to some embodiments of act 4106.

At act 4108, a first trench fill layer is formed between inner sidewalls of the first liner and over the front-side surface of the substrate. FIGS. 16-18 illustrate views 1600-1800 corresponding to some embodiments of act 4108.

At act 4110, a plurality of pixel devices are formed on the front-side surface of the substrate within an interconnect structure. Furthermore, a floating diffusion node is formed in the front-side of the substrate. FIGS. 19-20 illustrate cross-sectional views 1900-2000 corresponding to some embodiments of act 4110.

At act 4112, a thinning process is performed on a back-side surface of the substrate, where the thinning process exposes the full depth trench structure. FIGS. 21-22, and 43-44 illustrate views 2100-2200, and 4300-4400 corresponding to some embodiments of act 4112.

At act 4114, the back-side surface of the substrate is patterned to define a first partial depth isolation opening extending into the back-side surface of the substrate. FIGS. 23-25, and 45-46 illustrate views 2300-2500, and 4500-4600 corresponding to some embodiments of act 4114.

At act 4116, a controlled extension etch is performed on the back-side surface of the substrate to form a second partial depth isolation opening that is an extension of the first partial depth isolation opening. FIGS. 26-28 and 47-48 illustrate views 2600-2800 and 4700-4800 corresponding to some embodiments of act 4116.

At act 4118, a second liner and a second trench fill layer are deposited in the second partial depth isolation opening, thereby forming a partial depth isolation structure. FIGS. 29-31 illustrate views 2900-3100 corresponding to some embodiments of act 4118.

At act 4120, a plurality of light filters is formed over the back-side surface and a plurality of micro-lenses is formed over the plurality of light filters. FIGS. 32-33 illustrate views 3200-3300 corresponding to some embodiments of act 4120.

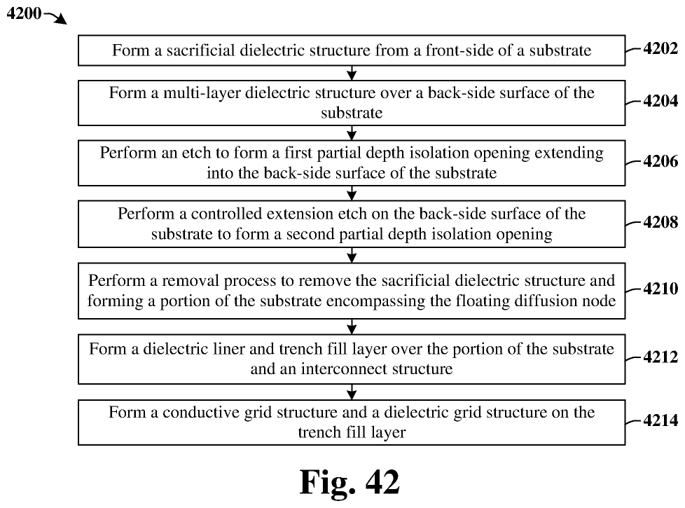

FIG. 42 illustrates some embodiments of a method 4200 of forming an image sensor comprising an isolation structure having a full depth isolation structure and a partial depth isolation structure with different depths and formed from the back-side of a substrate according to the present disclosure. Although the method 4200 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 4202, a sacrificial dielectric structure is formed from a front-side of a substrate laterally surrounding a floating diffusion node. FIG. 34 illustrates a cross-sectional view 3400 corresponding to some embodiments of act 4202.

At act 4204, a multi-layer dielectric structure is formed over a back-side surface of the substrate. FIG. 35 illustrates a cross-sectional view 3500 corresponding to some embodiments of act 4204.

At act 4206, an etch is performed to form a first partial depth isolation opening extending into the back-side surface of the substrate. FIG. 36 illustrates a cross-sectional view 3500 corresponding to some embodiments of act 4206.

At act 4208, a controlled extension etch is performed on the back-side surface of the substrate to form a second partial depth isolation opening that is an extension of the first partial depth isolation opening. FIG. 37 illustrates a cross-sectional view 3700 corresponding to some embodiments of act 4208.

At act 4210, a removal process is performed to remove the sacrificial dielectric structure forming a portion of the substrate disposed over and around a floating diffusion node. FIG. 38 illustrates a cross-sectional view 3800 corresponding to some embodiments of act 4210.

At act 4212, a dielectric liner and trench fill layer are deposited over the portion of the substrate and an interconnect structure. FIG. 39 illustrates a cross-sectional view 3900 corresponding to some embodiments of act 4212.

At act 4214, a conductive grid structure and a dielectric grid structure are formed on the trench fill layer. FIG. 40 illustrates a cross-sectional view 4000 corresponding to some embodiments of act 4214.

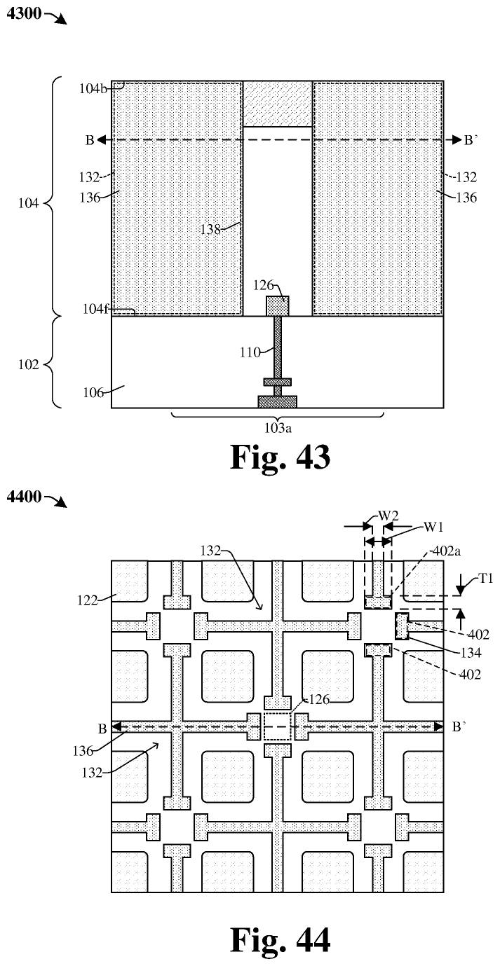

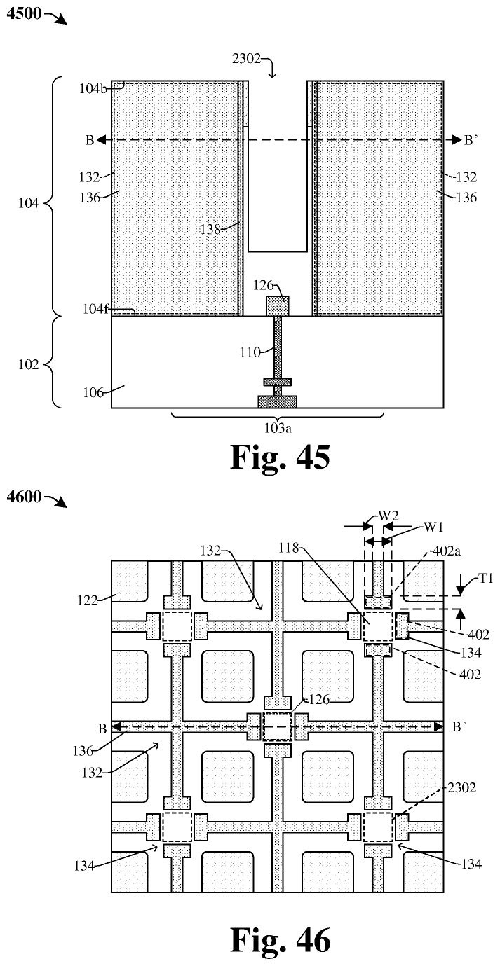

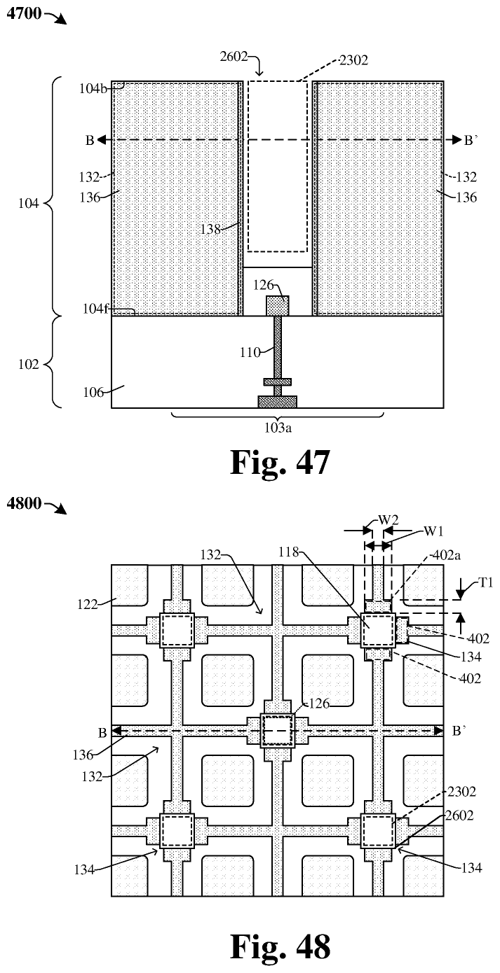

FIGS. 43-48 show various views 4300-4800 illustrating alternative embodiments for some aspects of the method flow shown in FIGS. 11-40 where the full depth isolation structure 132 includes one or more tab structures 402. Cross-sectional view 4300 and top view 4400 of FIGS. 43 and 44 show the full depth isolation structure 132 formed with one or more tab structures 402 as described in accordance with FIG. 4. Cross-sectional view 4500 and top view 4600 of FIGS. 45 and 46 show a first etch performed between inner opposing sidewalls of the one or more tab structures 402 to form a first partial depth isolation opening 2302. Aspects of forming the first partial depth isolation opening 2302 are described in accordance with FIGS. 23-25. The first partial depth isolation opening 2302 is a substantially rectangular shape when viewed from the top view 4400. Cross-sectional view 4700 and top view 4800 of FIGS. 47 and 48 show a second etch performed within the first partial depth isolation opening 2302 to form a second partial depth isolation opening 2602. The second etch is a controlled extension etch performed on the back-side surface 104b of the substrate 104 as described in accordance with FIGS. 26-28. The one or more tab structures 402 prevent the second etch from removing too much of the substrate 104 adjacent to the photodetectors 122 when forming the second partial depth isolation opening 2602. Subsequently, the partial depth isolation structure is formed according to the method steps as illustrated or described in FIGS. 29-31 where the partial depth isolation structure is formed with the substantially rectangular shape as shown in FIG. 4.

Accordingly, in some embodiments, the present disclosure relates to an image sensor that includes both partial and full depth isolation structures within a substrate to enhance photodetector performance. Furthermore, the full depth isolation structure can be formed from a front-side of a substrate comprising photodetectors, and the partial depth isolation structure can be formed from a back-side of the substrate.

In some embodiments, the present disclosure relates to a semiconductor device having a plurality of photodetectors disposed within a substrate, wherein the substrate has a front-side opposite a back-side. The semiconductor device has a floating diffusion node disposed in the substrate, where the photodetectors are disposed around the floating diffusion node. The semiconductor device has a trench isolation structure disposed within the substrate and laterally surrounding the photodetectors. The trench isolation structure comprises a first isolation structure disposed in the substrate and having a first depth, where the first isolation structure is disposed between adjacent photodetectors and is laterally offset from the floating diffusion node. The semiconductor device has a second isolation structure extending from the back-side of the substrate towards the floating diffusion node, where the second isolation structure directly overlies the floating diffusion node and has a second depth less than the first depth.

In some embodiments, the present disclosure relates to an image sensor having an interconnect structure disposed on a front-side surface of a substrate, where the substrate has a back-side surface opposite the front-side surface. The image sensor has a plurality of photodetectors disposed within the substrate. The image sensor has a partial depth isolation structure disposed within the substrate between the plurality of photodetectors, where the partial depth isolation structure extends from the back-side surface of the substrate towards the interconnect structure, and where the partial depth isolation structure has a bottom surface above the front-side surface of the substrate. The image sensor has a full depth isolation structure disposed within the substrate between the plurality of photodetectors, where the full depth isolation structure extends through a full depth of the substrate, and where the full depth isolation structure and the partial depth isolation structure together form at least a linear grid segment of a trench isolation structure.

In some embodiments, the present disclosure relates to a method of forming an image sensor, the method includes forming a photodetector within a substrate, where the substrate has a back-side surface that is opposite from a front-side surface. The method includes patterning the front-side surface of the substrate to form a full depth isolation structure opening through the substrate, where the full depth isolation structure opening surrounds a portion of the photodetector. The method includes forming a full depth isolation structure within the full depth isolation structure opening and patterning the back-side surface of the substrate to form a partial depth isolation structure opening surrounding a portion of the photodetector. The partial depth isolation structure opening has a bottom surface that is above the front-side surface of the substrate, and the partial depth isolation structure opening is formed between opposing edges of the full depth isolation structure. The method includes forming a partial depth isolation structure within the partial depth isolation structure opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of photodetectors disposed within a substrate, wherein the substrate has a front-side opposite a back-side;
a floating diffusion node disposed in the substrate, wherein the photodetectors are disposed around the floating diffusion node;
a trench isolation structure disposed within the substrate and laterally surrounding the photodetectors, the trench isolation structure comprising:
a first isolation structure disposed in the substrate and having a first depth, where the first isolation structure is disposed between adjacent photodetectors and is laterally offset from the floating diffusion node; and
a second isolation structure extending from the back-side of the substrate towards the floating diffusion node, wherein the second isolation structure directly overlies the floating diffusion node and has a second depth less than the first depth.

2. The semiconductor device of claim 1, wherein a liner layer is disposed between the first isolation structure and the second isolation structure, wherein the liner layer is disposed over the back-side of the substrate and covers a top surface of the first isolation structure.

3. The semiconductor device of claim 1, wherein the second isolation structure has a substantially rectangular shape when viewed from a top view, and wherein the second isolation structure is surrounded by the first isolation structure.

4. The semiconductor device of claim 1, wherein the first depth is equal to a height of the substrate.

5. The semiconductor device of claim 1, wherein a photodetector of the plurality of photodetectors has four sides, wherein the first isolation structure extends substantially parallel with a first side and a second side of the four sides of the photodetector, and wherein the second isolation structure extends substantially parallel with the first and second sides.

6. The semiconductor device of claim 1, wherein a top surface of the second isolation structure has a first width and a top surface of the first isolation structure has a second width, wherein the second width is less than the first width.

7. The semiconductor device of claim 6, wherein a bottom surface of the second isolation structure has a third width and a bottom surface of the first isolation structure has a fourth width, wherein the third width is less than the fourth width.

8. An image sensor, comprising:
an interconnect structure disposed on a front-side surface of a substrate, wherein the substrate has a back-side surface opposite the front-side surface;
a plurality of photodetectors disposed within the substrate;
a partial depth isolation structure disposed within the substrate between the plurality of photodetectors, wherein the partial depth isolation structure extends from the back-side surface of the substrate towards the interconnect structure, and wherein the partial depth isolation structure has a bottom surface above the front-side surface of the substrate; and
a full depth isolation structure disposed within the substrate between the plurality of photodetectors, wherein the full depth isolation structure extends through a full thickness of the substrate, and wherein the full depth isolation structure and the partial depth isolation structure together form at least a linear grid segment of a trench isolation structure.

9. The image sensor of claim 8, wherein the partial depth isolation structure extends laterally over the back-side surface of the substrate and overlies the full depth isolation structure and the plurality of photodetectors.

10. The image sensor of claim 8, wherein the full depth isolation structure comprises a plurality of tab structures that surround outer sidewalls of the partial depth isolation structure.

11. The image sensor of claim 8, wherein adjacent photodetectors of the plurality of photodetectors are separated by both the partial depth isolation structure and the full depth isolation structure.

12. The image sensor of claim 8, wherein from a top view a photodetector of the plurality of photodetectors has a first pair of edges that are opposite from one another and a second pair of edges that are opposite from one another, wherein the first pair of edges are rotated 90 degrees relative to the second pair of edges, and
the first pair of edges face the partial depth isolation structure, and where the second pair of edges face the full depth isolation structure.

13. The image sensor of claim 8, further comprising:
a floating diffusion node disposed within the substrate on the front-side surface of the substrate, wherein the floating diffusion node directly underlies a bottom surface of the partial depth isolation structure.

14. The image sensor of claim 13, wherein the floating diffusion node is laterally surrounded by the full depth isolation structure.

15. A method of forming an image sensor, the method comprising:
forming a photodetector within a substrate, wherein the substrate has a back-side surface that is opposite from a front-side surface;
patterning the front-side surface of the substrate to form a full depth isolation structure opening through the substrate, wherein the full depth isolation structure opening surrounds a portion of the photodetector;
forming a full depth isolation structure within the full depth isolation structure opening;
patterning the back-side surface of the substrate to form a partial depth isolation structure opening surrounding a portion of the photodetector, wherein the partial depth isolation structure opening has a bottom surface that is above the front-side surface of the substrate, and wherein the partial depth isolation structure opening is formed between opposing edges of the full depth isolation structure; and
forming a partial depth isolation structure within the partial depth isolation structure opening.

16. The method of claim 15, wherein the photodetector comprises four sides, and the full depth isolation structure opening is formed surrounding a portion of each of the four sides of the photodetector.

17. The method of claim 16, wherein the partial depth isolation structure opening is formed surrounding a portion of each of the four sides of the photodetector that is different than the portion of each of the four sides of the photodetector occupied by the full depth isolation structure.

18. The method of claim 15, wherein a liner is formed within the partial depth isolation structure opening and separates the full depth isolation structure from the partial depth isolation structure opening, and the partial depth isolation structure is formed on the liner.

19. The method of claim 15, wherein the back-side surface of the substrate is patterned with a dry etch to form the partial depth isolation structure opening, and the method further includes;
performing a wet etch on the partial depth isolation structure opening, wherein the wet etch extends the partial depth isolation structure opening in depth and width; and
forming the partial depth isolation structure within the partial depth isolation structure opening after performing the wet etch.

20. The method of claim 15, wherein the partial depth isolation structure is further formed over a back-side surface of the substrate and covering the full depth isolation structure.
